(19) United States
(12) Patent Application Publication
(10) Pub. No.: US 2016/0329001 A1
(43) Pub. Date: Nov. 10, 2016

(54) FASTENING ARRANGEMENT FOR A REPLACABLE VOLTAGE SOURCE FOR AN ELECTRONIC PRICE LABEL

(71) Applicant: MARIELLA LABELS OY, Vantaa (FI)

(72) Inventors: Göran SUNDHOLM, Tuusula (FI); Tero KALLIOINEN, Kirkkonummi (FI); Antti NURMI, Piikkiö (FI)

(73) Assignee: MARIELLA LABELS OY, Vantaa (FI)

(21) Appl. No.: 15/110,674

(22) PCT Filed: Dec. 8, 2014
(86) PCT No.: PCT/FI2014/050965

§ 371 Date: Jul. 8, 2016

(30) Foreign Application Priority Data
Jan. 16, 2014 (FI) 20145035

(51) Int. Cl. G09F 3/20; G09F 3/10

(52) U.S. Cl. CPC G09F 3/208; G09F 3/10; G11C 16/04

(57) ABSTRACT

Electronic price label and a fastening arrangement for a replacable voltage source for an electronic price label, which fastening arrangement includes a recess for the replacable voltage source in the body part of the electronic price label, a first electrical connector part and a second electrical connector part that are fitted into connection with the recess. The fastening arrangement further includes at least one fastening member including an adhesive surface. The replacable voltage source is detachably fastened to the electronic price label, e to the body part of it or to the rear surface of the electronic price label, by the aid of a fastening member including an adhesive surface.

### FIELD OF THE INVENTION

The invention relates to electronic price label systems. The invention relates more particularly to a fastening arrangement for a replacable voltage source for an electronic price label.

According to one embodiment of the invention the fastening arrangement according to the invention for a replacable voltage source can be used e.g. in various electronic price labels that are provided with an electronic display. These types of displays comprise e.g. electronic displays for showing the price information of products and other product information in retail stores and warehouses.

### BACKGROUND OF THE INVENTION

Conventionally the price information of price labels is changed manually when the price of a product changes. New price labels are printed onto paper or onto a corresponding material and these labels, with their new price markings, are manually disposed in locations reserved on shelves in sales premises. Consequently, an employee must first find the correct location for the price label to be updated, after which the previous price label is removed and discarded and the new price label is placed into its position. One drawback, among others, in this arrangement is that the arrangement is very laborious and the risk of errors is high. In the case of an error, e.g. a situation can arise in which the price information of a price label on the shelves is at variance with the price information of the checkout system.

In order to avoid the drawbacks described above, electronic systems have been developed wherein electronic price labels and the electronic displays of them are placed on the front edge of shelves or above them near the products, wherein the price information of the products can be changed centrally from the control center or corresponding of the system. This enables and significantly speeds up the updating of price information. The information on the displays can be updated in a wireline or wireless manner, depending on the system.

Known from publication WO 2009/103857A1 is a system in which wireless electronic price labels are used. The properties of the wireless, layer-structured, electronic price labels presented in the publication are excellent. Some situations have arisen, however, in which the battery of a price label empties and it is desired to replace it.

Also known in the art are electronic price labels in which it is possible to replace the battery. These electronic price labels have a hard shell and replacement of the battery has been enabled by means of a hard battery enclosure. These price labels are thus structurally hard and inflexible and are not flexible like the electronic price labels known from publication WO2009103857.

### SUMMARY OF THE INVENTION

The aim of the invention is to reduce the aforementioned problems and to simultaneously enable an inexpensive and reliable fastening arrangement for a replacable voltage source for an electronic price label.

The invention is based on a concept in which the voltage source of an electronic price label can be replaced and the voltage source is adapted to be fastened to the electronic price label by the aid of a fastening means comprising an adhesive surface.

The fastening arrangement according to the invention for a replacable voltage source for an electronic price label is characterized by what is stated in claim 1.

The embodiments of the fastening arrangement according to the invention for a replacable voltage source for an electronic price label are characterized by what is stated in claims 2-13.

The electronic price label according to the invention is characterized by what is stated in claim 14.

The embodiments of the electronic price label according to the invention are characterized by what is stated in claim 15.

The solution according to the invention has a number of important advantages compared to prior-art solutions. For example, compared to electronic price labels known in the art, which are described e.g. in publication WO2009103857, the voltage source of a price label according to the invention can be replaced and thus the price label does not need to be replaced with a new price label e.g. always when the battery empties or the voltage source fails. This saves costs as well as the natural environment.

On the other hand, when comparing the solution according to the invention to hard electronic price labels known in the art that have a replacable battery, with the solution according to the invention a flexible structure is enabled for the price label, in addition to the voltage source being replacable, which structure is more durable against external forces than the structures used by hard price labels that disintegrate easily e.g. when the price label is dropped on the ground or when someone steps on the price label. In addition to this, in the solution according to the invention detaching the voltage source does not stress the fastenings of the components as much as in prior art solutions, in which hard battery enclosures are used, because in prior art solutions the batteries are fixed firmly to the hard battery enclosures and, that being the case, a relatively large force is needed to detach a battery. Another advantage of this invention is that in the solution according to the invention the recess intended for the voltage source does not need to be precisely dimensioned to be the size of the replacable voltage source because the voltage source is fastened to the electronic price label by the aid of a fastening means comprising an adhesive surface.

This facilitates the manufacture of price labels according to the invention. As a result of this and also of the other structures of the solution according to the invention, the arrangement according to the invention is cheaper in price to implement than the structures of hard prior-art price labels provided with replacable batteries.

In one embodiment of the invention, in addition to the fastening of the voltage source, also at least a second electrical connector part, which connects the connection pole of the replacable voltage source to the electrical parts of the price label, can be fastened to the replacable voltage source by the aid of a fastening means comprising an adhesive surface. An advantage of this embodiment is that a reliable contact between the electrical connector part and the connection pole of the replacable voltage source is ensured.

In one embodiment of the invention, the electrical connector part can be fastened to the replacable voltage source and the replacable voltage source can be fastened to the electronic price label with one and the same fastening means comprising an adhesive surface. In a second embodiment of the invention the replacable voltage source is adapted to be fastened to the electronic price label with one fastening means comprising an adhesive surface and the electrical connector part is adapted to be fastened to the replacable voltage source with a second fastening means comprising an adhesive surface. An advantage of this embodiment is that the fastening of the electrical connector part and the voltage source to each other and the fastening of the voltage source and the electronic price label to each other are easier because it is done in two phases.

### DESCRIPTION OF THE FIGURES

In the following, the invention will be described in more detail by the aid of an example of its embodiment with reference to the attached drawings, wherein

FIG. 1 presents a simplified view of the structure of an electronic price label according to one embodiment of the invention as seen from the front side of the electronic price label,

FIG. 2 presents a simplified view of the structure of an electronic price label according to one embodiment of the invention and a fastening arrangement for a replacable voltage source as seen from the rear side of the electronic price label,

FIG. 3A presents an embodiment of the invention cross-sectioned along the line A-A of FIG. 2, in which the replacable voltage source is fastened by the aid of one fastening means,

FIG. 3B presents an embodiment of the invention cross-sectioned along the line B-B of FIG. 2, in which the replacable voltage source is fastened by the aid of one fastening means,

FIG. 3C presents an embodiment of the invention cross-sectioned along the line A-A of FIG. 2, in which the replacable voltage source is fastened by the aid of one fastening means,

FIG. 3D presents an embodiment of the invention cross-sectioned along the line B-B of FIG. 2, in which the replacable voltage source is fastened by the aid of one fastening means,

FIG. 3E presents an embodiment of the invention cross-sectioned along the line C-C of FIG. 2, in which the replacable voltage source is fastened by the aid of

FIG. 3F presents an embodiment of the invention cross-sectioned along the line C-C of FIG. 2, in which the replacable voltage source is fastened by the aid of one fastening means,

FIG. 3G presents an embodiment of the invention cross-sectioned along the line D-D of FIG. 2, in which the replacable voltage source is fastened by the aid of one fastening means,

FIG. 3H presents an embodiment of the invention cross-sectioned along the line D-D of FIG. 2, in which the replacable voltage source is fastened by the aid of one fastening means,

FIG. 4 presents an embodiment of the invention cross-sectioned along the line B-B of FIG. 2, in which the fastening means adapts according to the structure of the rear part of the electronic price label,

FIG. 5A presents an embodiment of the invention cross-sectioned along the line B-B of FIG. 2, in which the replacable voltage source is fastened by the aid of two fastening means,

FIG. 5B presents an embodiment of the invention cross-sectioned along the line B-B of FIG. 2, in which the replacable voltage source is fastened by the aid of two fastening means,

FIG. 5C presents an embodiment of the invention cross-sectioned along the line B-B of FIG. 2, in which the replacable voltage source is fastened by the aid of two fastening means,

FIG. 6A presents an embodiment of the invention cross-sectioned along the line B-B of FIG. 2, in which there is a recess for the fastening means comprising an adhesive surface in the rear wall of the electronic price label,

FIG. 6B presents an embodiment of the invention cross-sectioned along the line B-B of FIG. 2, in which there is a recess for the fastening means comprising an adhesive surface in the rear wall of the electronic price label, and

FIG. 6C presents an embodiment of the invention cross-sectioned along the line B-B of FIG. 2, in which there is a recess for the fastening means comprising an adhesive surface in the rear wall of the electronic price label,

FIG. 7 presents a magnified view of the structure of a fastening arrangement for the replacable voltage source of an electronic price label according to an embodiment of the invention, in which the replacable voltage source is fastened by the aid of two fastening means,

FIG. 8 presents a magnified view of the structure of a fastening arrangement for the replacable voltage source of an electronic price label according to an embodiment of the invention, in which the replacable voltage source is fastened by the aid of two fastening means,

FIG. 9 presents a magnified view of the structure of a fastening arrangement for the replacable voltage source of an electronic price label according to an embodiment of the invention, in which a second electrical connector part is in a recess on the side of the voltage source,

FIG. 10 presents the rear cover of a price label, said cover being according to an embodiment of the invention,

FIG. 11 presents the rear cover of a price label, said cover being according to an embodiment of the invention.

### DETAILED DESCRIPTION OF THE INVENTION

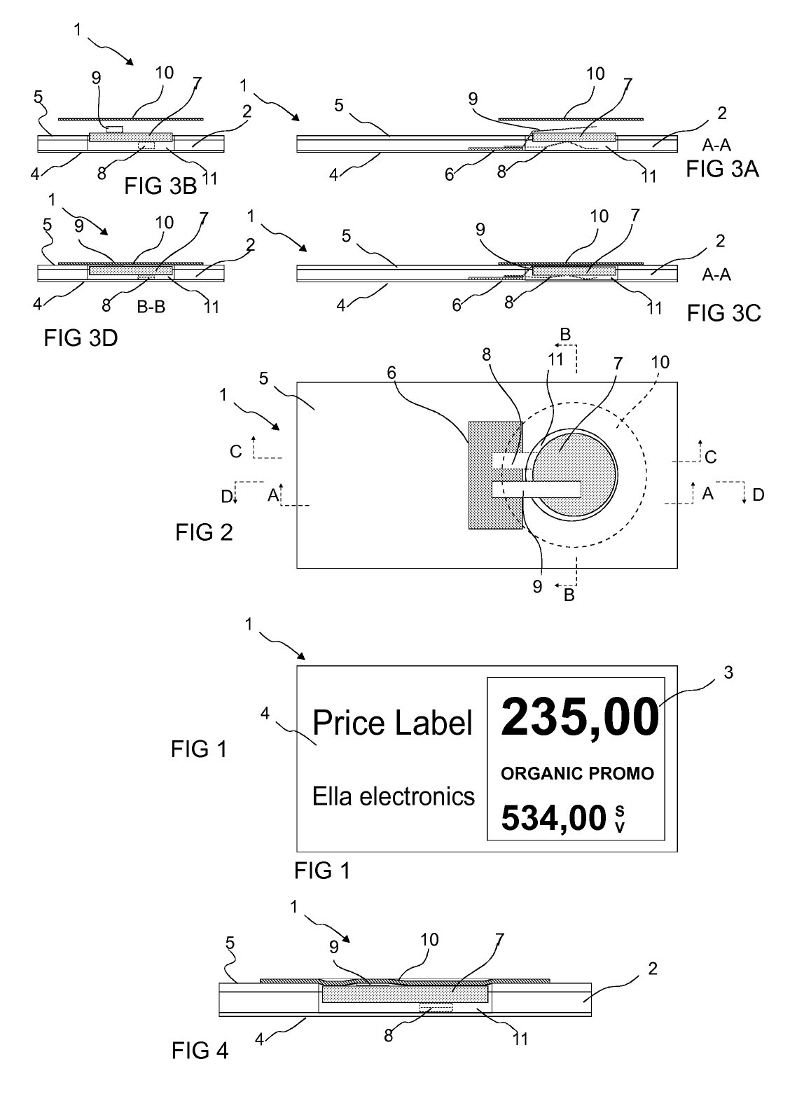

FIG. 1 presents a diagrammatic and simplified view of an electronic price label 1 according to the invention. The electronic price label 1 typically comprises a laminate display 3, which is arranged to display the price information and/or product information of a product. Also other information relating to the product, such as e.g. the name of the product, can be presented on the front surface 4 of an electronic price label. The display 3 of an electronic price label is provided with display segments or pixels. The price label 1 resembles a price label of paper, on which price label the required prices of products and other necessary symbols are formed by changing the colors of the segments or pixels of an essentially dichromatic display 3.

One layer of the display 3 is e.g. an active ink layer. The ink layer contains a number of microcapsules, which are filled with a liquid and which contain e.g. essentially black particles, which have a positive surface charge and the location of which is controlled with an electrical field in such a way that in the desired display segments the black particles are on, wherein the aforementioned display segment appears black when it is viewed from above, and in the other display segments the white particles are on, wherein these display segments appear white when viewed from above. The background of the display 3 is formed from the same microcapsules, wherein e.g. price information can be displayed as dark numbers against a light background or, if so desired, vice versa. This type of display, which is used, can be an electrophoretic microcapsule display laminate described e.g. in Finnish patent application FI 20050192.

FIG. 2 presents a simplified view of the structure of an electronic price label according to one embodiment of the invention and a fastening arrangement for a replacable voltage source as seen from the rear side of the electronic price label. The electronic price label 1 comprises a recess 11 for the replacable voltage source 7 in the body part 2 of the electronic price label, which body part 2 can be essentially flexible. In one embodiment of the invention, in the rear surface 5 of the price label is a hole essentially the same size as the recess and aligned with it. A first electrical connector part 8 and a second electrical connector part 9 are fitted into connection with the recess 11 in the body part, by the aid of which electrical connector parts the replacable voltage source 7 can be connected to the electrical parts of the electronic price label, e.g. to a circuit board 6. The replacable voltage source can be e.g. a battery or an accumulator. In one embodiment of the invention, the first electrical connector part 8 and the second electrical connector part 9 are arranged in such a way that when the replacable voltage source 7 is installed into its position it is between the first 8 and the second electrical connector part 9 and the connection poles of the replacable voltage source are in continuous contact with the electrical connector parts 8, 9.

The fastening arrangement further comprises at least one fastening means 10 comprising an adhesive surface, the location of which is marked in FIG. 2 with a dashed line. The fastening means 10 comprising an adhesive surface has a first and a second side, and an adhesive surface is fitted to at least one side of the fastening means. The side of the fastening means 10 on which the adhesive surface is can be covered throughout by the adhesive surface or alternatively the adhesive surface can be formed on only a part of this surface. In one embodiment of the invention, the fastening means 10 comprising an adhesive surface is flexible. In one embodiment of the invention, the fastening means 10 comprising an adhesive surface is a sticker. The fastening means 10 comprising an adhesive surface can be e.g. circular or rectangular in shape.

In the solution of the invention the replacable voltage source 7 is adapted to be fastened to the electronic price label, e.g. to the body part 2 of it or to the rear surface 5 of the electronic price label, by the aid of the fastening means 10 comprising an adhesive surface. When installed into its position the surface comprising an adhesive surface of the fastening means 10 is the surface on the side of the electronic price label. The fastening means 10 comprising an adhesive surface thus fastens to the price label and to the voltage source by means of its adhesive surface. In one embodiment of the invention, when installed into its position the fastening means 10 of the voltage source, said fastening means to be fastened to the price label and comprising an adhesive surface, extends to outside the edges of the recess 11 and thus covers the recess 11.

In one embodiment of the invention, also the second electrical connector part 9 is adapted to be fastened to the replacable voltage source by the aid of the fastening means 10 comprising an adhesive surface. In the fastening the second electrical connector part 9 remains between the fastening means 10 and the replacable voltage source 7 and in this way the adhesive surface fastens the replacable voltage source 7 and the second electrical connector part 9 to each other. By means of this, a good and reliable contact between the connection pole of the replacable voltage source and the second electrical connector part 9 can be ensured.

In one embodiment of the invention, the second electrical connector part 9 can be fastened to the replacable voltage source 7 and the replacable voltage source 7 can be fastened to the electronic price label with one and the same fastening means 10 comprising an adhesive surface.

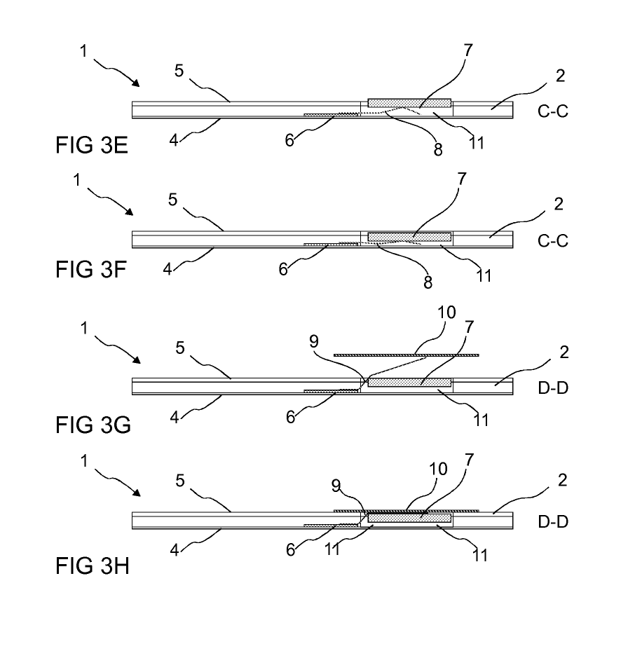

FIGS. 3A-3H present cross-sections of an embodiment of a fastening arrangement according to the invention, in the event of installing a replacable voltage source, in which embodiment one fastening means is used in fastening the voltage source to the price label.

FIG. 3A presents an embodiment of the invention cross-sectioned along the line A-A of FIG. 2, in which embodiment the replacable voltage source is fastened by the aid of one fastening means. FIG. 3A presents a situation in which the replacable voltage source is being installed in the recess 11. On the base of the recess 11 and below the replacable voltage source is a first electrical connector part 8, the purpose of which is to form a contact with the first connection pole of the replacable voltage source 7. Above the replacable voltage source 7, i.e. on the rear side of the electronic price label, is a second electrical connector part 9, the purpose of which is to form a contact between the replacable voltage source 7 and the second connection pole. The replacable voltage source 7 thus remains between the first electrical connector part 8 and the second electrical connector part 9. In the embodiment presented in FIGS. 3A-3H the first electrical connector part 8 forms a spring means, which is adapted to push the voltage source 7 against the second electrical connector part 9.

FIG. 3B presents the situation presented in FIG. 3A, in which the replacable voltage source 7 is being installed into the recess 11 of the body part of the price label, as a cross-section along the line B-B of FIG. 2. According to FIG. 3B the first electrical connector part 8 remains under the replacable voltage source 7 and the second electrical connector part 9 remains on the opposite side of the replacable voltage source 7.

FIG. 3C presents, as a cross-section along the line A-A of FIG. 2, the embodiment presented in FIG. 3A in the situation in which the replacable voltage source 7 and the fastening means 10 comprising an adhesive surface have been installed into their positions. The fastening means 10 comprising an adhesive surface, when installed into its position, fastens the replacable voltage source to the rear wall 5 of the electronic price label. At the same time the fastening means 10 comprising an adhesive surface fastens the second electrical connector part 9 to the replacable voltage source 7, because the second electrical connector part 9 remains between the replacable voltage source 7 and the fastening means 10 comprising an adhesive surface.

FIG. 3D presents the same situation as in FIG. 3C but as a cross-section along the line B-B of FIG. 2. From FIG. 3D it is seen, as it is from FIG. 3C, how by means of the solution according to the invention the replacable voltage source 7 is fastened to the electronic price label and how at the same time the electrical contacts between the first electrical connector part 8, the second electrical connector part 9 and the connection poles of the replacable voltage source are, owing to the tight fastening, reliable.

FIGS. 3E and 3F are cross-sections along the line C-C of FIG. 2. In FIG. 3E the replacable voltage source 7 is being installed into the recess 11 and in FIG. 3F the replacable voltage source has been installed onto the base of the recess 11 against the first electrical connector part 8.

FIGS. 3G and 3H are cross-sections along the line D-D of FIG. 2. In FIG. 3G the fastening means 10 comprising an adhesive surface is ready for installation, but it has not yet been fastened into its position. The second electrical connector part 9 has been fitted between the fastening means 10 comprising an adhesive surface and the replacable voltage source 7. In FIG. 3H the fastening means 10 comprising an adhesive surface has been fastened into its position and thus the second electrical connector part is fastened to the replacable voltage source 7 and the replacable voltage source 7 is fastened to the rear wall 5 of the electronic price label.

If the fastening means 10 comprising an adhesive surface is of a flexible material, it adapts itself according to the structure of the rear part of the electronic price label. This is presented in FIG. 4, which presents a cross-section of the fastening arrangement along the line B-B of FIG. 2.

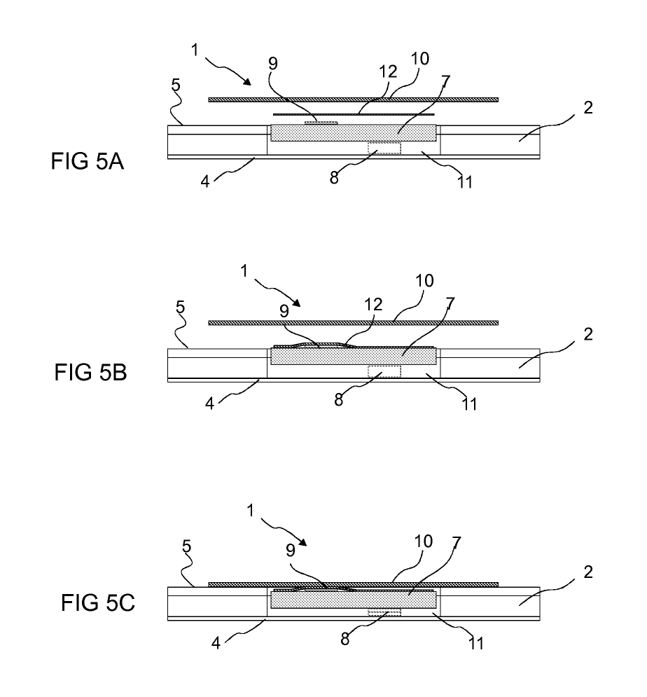

FIGS. 5A-5C present cross-sections of an embodiment of a fastening arrangement according to the invention, in which embodiment the replacable voltage source is fastened to the electronic price label and to the connector part by the aid of two fastening means. As in the embodiment described in FIGS. 3A-3H, in this embodiment also the replacable voltage source 7 is adapted to be fastened to the electronic price label, e.g. to the body part 2 of it or to the rear surface 5 of the electronic price label, by the aid of the first fastening means 10 comprising an adhesive surface. In addition to this, the second electrical connector part 9 is adapted to be fastened to the replacable voltage source 7 by the aid of the second fastening means 12 comprising an adhesive surface. FIGS. 5A-5C present a fastening arrangement according to this embodiment as a cross-section along the line B-B of FIG. 2.

The second fastening means 12 comprising an adhesive surface can be smaller in size than the first fastening means 10 comprising an adhesive surface. The second fastening means 12 comprising an adhesive surface can be e.g. essentially the same size or smaller than the replacable voltage source and/or the connection pole of the replacable voltage source.

FIG. 5A presents a situation in which the replacable voltage source has been installed into the recess 11 of the body part of the price label. The first electrical connector part 8 remains below the replacable voltage source 7 and the second electrical connector part 9 remains on the opposite side of the replacable voltage source 7. The first fastening means 10 comprising an adhesive surface and the second fastening means 12 comprising an adhesive surface are aligned into their correct positions, but they are not yet fastened.

FIG. 5B presents a situation in which the second fastening means 12 comprising an adhesive surface has been installed into its position essentially on top of the voltage source in such a way that the second electrical connector part 9 remains between the replacable voltage source 7 and the second fastening means 12 comprising an adhesive surface, thus fastening the second electrical connector part 9 to the replacable voltage source 7. The first fastening means comprising an adhesive surface is not yet fastened into its position.

FIG. 5C presents a situation in which the first fastening means 10 comprising an adhesive surface has been installed into its position on top of the voltage source, the second fastening means 12 comprising an adhesive surface and the recess 11. The fastening means 10 comprising an adhesive surface, when installed into its position, fastens the replacable voltage source 7 to the rear wall 5 of the electronic price label. At the same time the first fastening means 10 comprising an adhesive surface fastens to the second fastening means 12 comprising an adhesive surface. Thus the replacable voltage source 7 has been fastened to the electronic price label and the electrical contacts between the first and second electrical connector part and the connection poles of the replacable voltage source are, owing to the tight fastening, reliable.

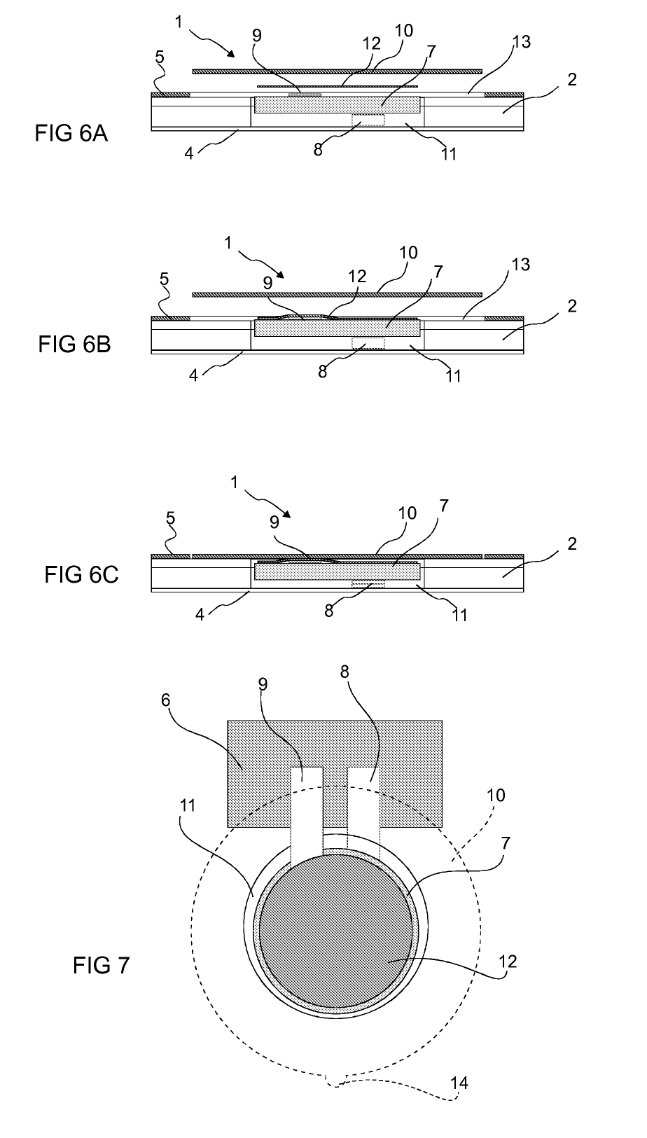

FIGS. 6A-6C present cross-sections of an embodiment of a fastening arrangement according to the invention, in which there is a recess for the fastening means comprising an adhesive surface in the rear wall of the electronic price label. As in the embodiment described in FIGS. 5A-5C, in this embodiment also the replacable voltage source 7 is adapted to be fastened to the electronic price label, e.g. to the body part 2 of it or to the rear surface 5 of the electronic price label, by the aid of the first fastening means 10 comprising an adhesive surface, and the second electrical connector part 9 is adapted to be fastened to the replacable voltage source 7 by the aid of the second fastening means 12 comprising an adhesive surface. FIGS. 6A-6C present a fastening arrangement according to this embodiment as a cross-section along the line B-B of FIG. 2.

FIGS. 6A-6C differ to the embodiment presented by FIGS. 5A-5C in that a recess 13 for the fastening means 10 comprising an adhesive surface is arranged in the rear part, e.g. in the rear wall 5, of the price label. In this case when the fastening means 10 comprising an adhesive surface is fitted into its position, the rear part of the price label is essentially flat.

A recess for a fastening means comprising an adhesive surface can also be formed with an embodiment wherein only one fastening means comprising an adhesive surface is used to fasten the replacable voltage source to the electronic price label and the electrical connector part to the replacable voltage source. In this case also the recess is arranged in such a way that the rear part of the price label is essentially flat when the fastening means comprising an adhesive surface is fitted into its position.

FIG. 7 presents a magnified view of the structure of a fastening arrangement for the replacable voltage source of an electronic price label according to an embodiment of the invention, in which the replacable voltage source is fastened by the aid of two fastening means. FIG. 7 presents the recess 11 for the replacable voltage source 7 and the first electrical connector part 8 and the second electrical connector part 9 fitted into connection with the recess 11, by the aid of which electrical connector parts the replacable voltage source 7 can be connected to the electrical parts of the electronic price label, e.g. to a circuit board 6. The first 8 and second 9 electrical connector part are arranged in such a way that when the replacable voltage source 7 is installed into its position it is between the first 8 and the second electrical connector part 9 and the connection poles of the replacable voltage source are in continuous contact with the electrical connector parts. The second fastening means 12 comprising an adhesive surface has been installed into its position essentially on top of the voltage source 7 in such a way that the second electrical connector part 9 remains between the replacable voltage source 7 and the second fastening means 12 comprising an adhesive surface, thus fastening the second electrical connector part 9 to the replacable voltage source 7. FIG. 6 presents with a dashed line the location into which the fastening means 10 comprising an adhesive surface is fastened on top of the second fastening means 12 comprising an adhesive surface

When it is desired to replace the replacable voltage source of the electronic price label according to the invention, the fastening means comprising an adhesive surface is detached at least partly from the electronic price label. In this case the replacable voltage source is no longer fastened to the price label and it can be removed from the recess and from between the connector parts. The fastening means comprising an adhesive surface can be detached from the electronic price label without the electronic price label being damaged. In one embodiment of the invention, the fastening means comprising an adhesive surface can be fastened to the electronic price label again after the detachment of the fastening means.

In one embodiment of the invention, markings facilitating opening are made on the fastening means comprising an adhesive surface, which markings facilitate the opening and/or removing of the fastening means. The markings are made in such a way that by means of them a user sees from which direction the fastening means is opened and how far the fastening means needs to be opened, so that the voltage source can be detached from the electronic price label without damaging the price label. The markings can be made e.g. by marking with printing ink, by painting, by printing, or by making a pre-cutting or perforation in the fastening means. If two fastening means comprising an adhesive surface are used for fastening the replacable voltage source, both of them or either one of them can have markings for facilitating the detachment of the fastening means.

In one embodiment of the invention, the fastening means comprises an indicator, which shows whether the fastening means comprising an adhesive surface, e.g. a sticker, has been opened.

A fastening means 10 comprising an adhesive surface can also have the area 14, presented in FIG. 7, extending from the edge of the fastening means, by means of which area a fastening means comprising an adhesive surface, e.g. a sticker, can be opened or removed easily. In one embodiment of the invention, an area extending from the edge of the fastening means has no adhesive surface, in which case it is easier to grip the area extending from the edge of the fastening means, and this further facilitates the opening and/or removing of the fastening means. If two fastening means comprising an adhesive surface are used for fastening the replacable voltage source, both of them or either one of them can have an area extending from the edge of the fastening means.

In one embodiment of the invention, a recess for the price label can be arranged also in the area 14 extending from the edge of the fastening means, said area being presented in FIG. 7. The recess can also be made to be larger than the area 14 extending from the edge of the fastening means, in which case it is easier for a user to grip the area 14 extending from the edge of the fastening means.

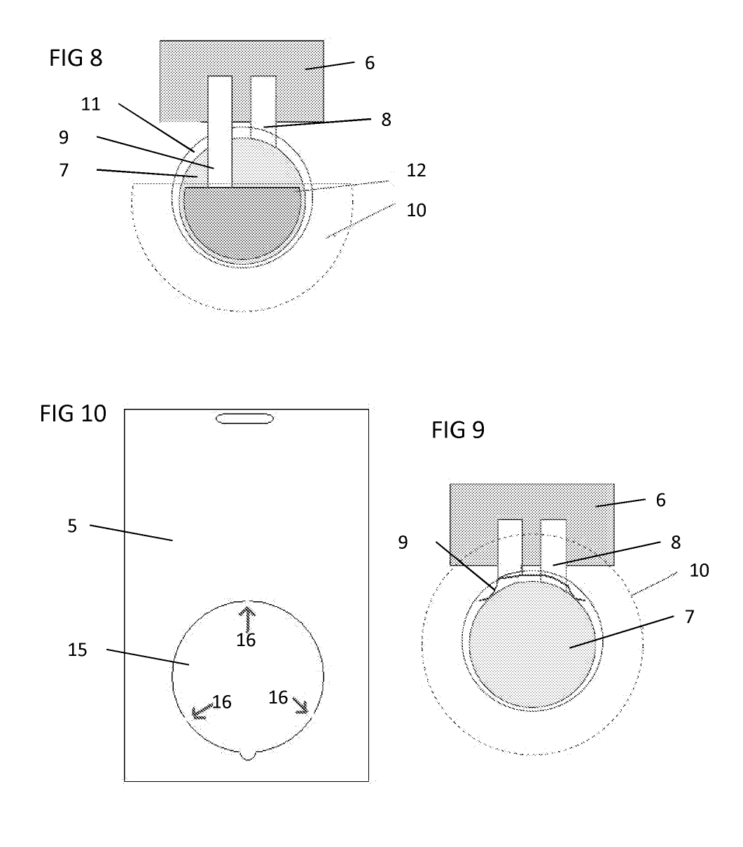

FIG. 8 presents a magnified view of the structure of a fastening arrangement for the replacable voltage source of an electronic price label according to an embodiment of the invention, in which the replacable voltage source is fastened by the aid of two fastening means. The solution of the figure is otherwise of the same kind as the embodiment presented in FIG. 7, but the first fastening means 10 comprising an adhesive surface and the second fastening means 12 comprising an adhesive surface of the embodiment presented in FIG. 8 are essentially semicircular in shape. The first fastening means 10 comprising an adhesive surface and/or the second fastening means 12 comprising an adhesive surface can also be of other shapes, e.g. circular and truncated at one edge. Also the aperture in the rear surface is essentially semicircular in shape or circular in shape and truncated at one edge, e.g. at the same edge as the first fastening means 10 comprising an adhesive surface and/or the second fastening means 12 comprising an adhesive surface. In this case a part of the recess is below the rear surface. When installed into its position also the voltage source 7 is situated partly below the rear surface and the rear surface forms a support for the voltage source 7 and for the second electrical connector part 9. In this embodiment also the replacable voltage source 7 is adapted to be fastened to the electronic price label, e.g. to the body part 2 of it or to the rear surface 5 of the electronic price label, by the aid of a first fastening means 10 comprising an adhesive surface, and the second electrical connector part 9 is adapted to be fastened to the replacable voltage source 7 by the aid of a second fastening means 12 comprising an adhesive surface.

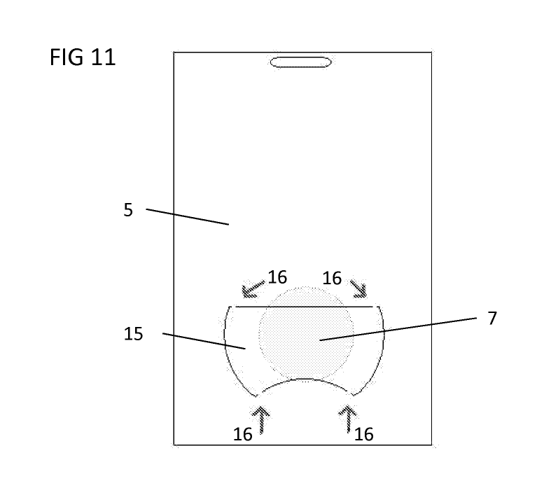

An advantage of the embodiment presented in FIG. 8 is that because voltage source 7, when installed into its position, and the second electrical connector part 9 are situated partly below the rear surface, the rear surface, in addition to the fastening means comprising an adhesive surface, also supports them. In this case the forces exerted on the fastening means 10 comprising an adhesive surface, e.g. the spring force formed by the first electrical connector part, are not as large as in an embodiment in which the aperture of the rear wall is of essentially the same size as the voltage source and/or the recess. Thus the fastening means 10 remains in its position more reliably and the contacts between the connection poles of the voltage source and the electrical connector parts are also reliable. The solutions of the embodiment also have an advantage when replacing the voltage source when the fastening means comprising an adhesive surface is removed. In this case the rear wall partly on top of the voltage source and second electrical connector supports the structures of the price label, e.g. the electrical connector parts 8, 9 and the circuit board 6. When it is desired to replace the replacable voltage source 7, it is threaded out of the recess and a new voltage source 7 threaded into the recess, the thin end of the voltage source first. The aperture in the rear surface can be essentially smaller than the power source and/or the recess 11 and e.g. semicircular or circular with one edge truncated, also in the other embodiments of the invention. The aperture in the rear surface can also be the same shape as the cover part of the rear wall presented in FIG. 11, in which case the rear surface forms a support for the voltage source on two sides, e.g. on opposite sides of the recess for the voltage source.

FIG. 9 presents a magnified view of the structure of a fastening arrangement for the replacable voltage source of an electronic price label according to an embodiment of the invention. The structure presented in FIG. 9 is otherwise of the same kind as the structure presented in FIGS. 3A-3H, in which one fastening means comprising an adhesive surface is used for fastening the voltage source, but in this embodiment the second electrical connector part 9 is fitted into the edge of the recess on the side of the voltage source. The second electrical connector part 9 forms in this embodiment a spring means, which is arranged to press against the flank of the voltage source. In this case it would be good for the body part of the price label to be tight, at least at the point of the second connector part, so that the second connector part does not press to deep inside the body part. In this embodiment the voltage source can be installed directly from the rear part of the price label and a second fastening means comprising an adhesive surface is not needed to fasten the voltage source to the second electrical connector part because the second electrical connector part creates a contact to the second connection pole of the voltage source by pressing between the edge of the recess and the connection pole that is on the edge of the voltage source.

The invention also relates to an electronic price label comprising a fastening arrangement according to the invention. In one embodiment of the invention, the electronic price label comprises a memory, which is adapted to retain information when the current is disconnected. The memory can be e.g. EEPROM (Electronically Erasable Programmable Read-Only Memory) memory. By means of the memory the information in the memory of the electronic label can be retained also during replacement of the voltage source and the electronic price label does not have to be reprogrammed after replacement of the voltage source.

FIG. 10 presents the rear surface, e.g. the rear cover, of an electronic price label according to an embodiment of the invention. In one embodiment of the invention, in the manufacture of a price label the rear cover is installed on the rear side of the electronic price label only when the voltage source is already in its position in the recess. Also a second fastening means comprising an adhesive surface can be already installed to fasten the voltage source to the second electrical connector part. A cover part 15 can be formed on the rear cover, e.g. by stamping and by leaving the cover part 15 attached at certain parts. In this case the necks 16 formed in the rear cover keep the cover part in its position with respect to the other parts of the rear cover.

The cover part 15 can comprise an adhesive surface at least at the point of the replacable voltage source and in this case the cover part 15 functions as a fastening means comprising an adhesive surface, which fastens the replacable power source to the price label. When replacing the voltage source, the cover part is torn open, in which case the voltage source becomes visible and it can be replaced. When a new voltage source has been installed into its position, it can be fastened again with an additional sticker, which is slightly larger than the detached or opened cover part. By means of the perforation of the cover, it is seen whether the cover part has been opened. The cover part can be fully circular in shape, semicircular in shape or of circular shape but truncated at one edge as in FIG. 8. The structure under the cover part can be according to what is presented in the preceding embodiments.

In one embodiment of the invention, an adhesive surface is arranged on the rear side of the body part of the price label, e.g. on the whole area of the rear side of the price label, with which adhesive surface the rear cover can be fastened to the price label. In this case the rear cover does not need its own glue when it is fastened to the body part of the price label. A double-sided fastening means comprising an adhesive surface, e.g. a sticker, that is e.g. round and is slightly smaller than the voltage source can be placed on top of the replacable voltage source, which fastening means grips both the voltage source and the rear cover. In this case, when replacing the voltage source, when the cover part 15 is detached the voltage source detaches along with it owing to the double-sided sticker.

In a second embodiment of the invention there is no glue on the body part of the price label. An adhesive area the size of the body part is pressed onto the rear cover, which adhesive area in the final assembly also grips the voltage source. In this case when replacing the voltage source the glue of the rear cover also detaches the voltage source. In this embodiment it is advantageous to use a cover part 15 that is at least essentially the size of the voltage source, so that the voltage source can be detached from the recess by pulling directly upwards.

FIG. 11 presents the same type of rear surface of the price label as in FIG. 10, but in this embodiment the cover part 15 and the aperture of the cover part are of different shapes than in FIG. 10. In the case of this embodiment a part of the recess for the voltage source is below the rear surface when the rear wall is fastened into its position on the price label. When installed into its position also the voltage source 7 is situated partly below the rear surface and the rear surface forms a support for the voltage source 7 and for the second electrical connector part 9. In the case of this embodiment the rear surface forms a support for the voltage source on two sides, e.g. on opposite sides of the recess for the voltage source. The support to be formed on top of the voltage source and on top of the recess for the voltage source can extend to farther from one edge of the recess than from the other edge. In one embodiment of the invention, the rear surface extends from one side of the voltage source to on top of the recess of the voltage source only to the extent that it supports the voltage source but at the same time the voltage source can be pushed into its position in such a way that it remains at both of its edges below the rear wall. FIG. 11 presents the stamping pattern of the rear cover, but for the sake of clarity the location of the voltage source with respect to the rear cover, when the rear cover is installed into its position, is also sketched in it.

In the case of the embodiment presented in FIG. 11 it is advantageous that the voltage source recess in the body of the price label is essentially the size of the voltage source and the rear cover is installed precisely in relation to the body part of the label so that the supports being formed from the rear wall on top of the recess keep the voltage source reliably in its position and enable detachment of the voltage source. In this case a fastening means comprising an adhesive surface is not necessarily needed for fastening the voltage source to the price label.

The rear wall of FIG. 11 can be fastened to the price label structure in a similar manner to the rear wall presented in FIG. 10.

It is obvious to the person skilled in the art that the invention is not limited to the embodiments presented above, but that it can be varied within the scope of the claims presented below. The characteristic features presented in the description mentioned in conjunction with each other can also be independent characteristic features.

1. Fastening arrangement for a replacable voltage source for an electronic price label, which fastening arrangement comprises a recess for the replacable voltage source in the body part of the electronic price label, a first electrical connector part and a second electrical connector part that are fitted into connection with the recess, wherein:
the fastening arrangement further comprises at least one fastening means comprising an adhesive surface, and in that
the replacable voltage source is adapted to be detachably fastened to the electronic price label, e.g. to the body part of it or to the rear surface of the electronic price label, by the aid of a fastening means comprising an adhesive surface, and
wherein the second electrical connector part is adapted to be fastened to the replacable voltage source by the aid of a fastening means comprising an adhesive surface.

2. Fastening arrangement according to claim 1, wherein the first electrical connector part and the second electrical connector part are arranged in such a way that the replacable voltage source when installed into its position is between the first electrical connector part and the second electrical connector part and the connection poles of the replacable voltage source are in continuous contact with the first electrical connector part and the second electrical connector part.

3. Fastening arrangement according to claim 1, wherein the replacable voltage source is a battery or an accumulator.

4. Fastening arrangement according to claim 1, wherein the body part, front surface and/or rear surface of the price label is essentially flexible.

5. Fastening arrangement according to claim 1, wherein the first electrical connector part forms a spring means, which is adapted to push the replacable voltage source against a second electrical connector part.

6. Fastening arrangement according to claim 1, wherein the fastening means comprising an adhesive surface is flexible.

7. Fastening arrangement according to claim 1, wherein the fastening means comprising an adhesive surface is a sticker.

8. Fastening arrangement according to claim 1, wherein the fastening means comprising an adhesive comprises an area extending from the edge of the fastening means, said area having no adhesive surface.

9. Fastening arrangement according to claim 1, wherein the second electrical connector part can be fastened to the replacable voltage source and the replacable voltage source can be fastened to the electronic price label with one and the same fastening means comprising an adhesive surface.

10. Fastening arrangement according to claim 1, wherein the replacable voltage source is adapted to be fastened to the electronic price label with one fastening means comprising an adhesive surface and the second electrical connector part is adapted to be fastened to the replacable voltage source with a second fastening means comprising an adhesive surface.

11. Fastening arrangement according to claim 1, wherein the fastening means of the replacable voltage source, said fastening means to be fastened to the price label and comprising an adhesive surface, extends when installed into its position to outside the edges of the recess and covers the recess.

12. Fastening arrangement according to claim 1, wherein the rear surface of the body part further comprises a recess for the fastening means comprising an adhesive surface, in which case the rear part of the price label is essentially flat when the fastening means comprising an adhesive surface is fitted into its position.

13. Electronic price label, wherein it comprises a fastening arrangement for a replacable voltage source, said fastening arrangement being according to claim 1.

14. Electronic price label according to claim 13, wherein it further comprises a memory, e.g. EEPROM (Electronically Erasable Programmable Read-Only Memory) memory, which is adapted to retain information when the current is disconnected.

15. Fastening arrangement according to claim 2, wherein the replacable voltage source is a battery or an accumulator.

16. Fastening arrangement according to claim 2, wherein the body part, front surface and/or rear surface of the price label is essentially flexible.

17. Fastening arrangement according to claim 3, wherein the body part, front surface and/or rear surface of the price label is essentially flexible.

18. Fastening arrangement according to claim 2, wherein the first electrical connector part forms a spring means, which is adapted to push the replacable voltage source against a second electrical connector part.

19. Fastening arrangement according to claim 3, wherein the first electrical connector part forms a spring means, which is adapted to push the replacable voltage source against a second electrical connector part.

20. Fastening arrangement according to claim 4, wherein the first electrical connector part forms a spring means, which is adapted to push the replacable voltage source against a second electrical connector part.
